(19) United States
(12) Patent Application Publication
(10) Pub. No.: US 2011/0121424 A1
(43) Pub. Date: May 26, 2011

(54) LOW OXYGEN CONTENT SEMICONDUCTOR MATERIAL FOR SURFACE ENHANCED PHOTONIC DEVICES AND ASSOCIATED METHODS

(76) Inventors: James Carey, Waltham, MA (US); Xia Li, Beverly, MA (US); Susan Alie, Stoneham, MA (US); Martin U. Pralle, Wayland, MA (US)

(21) Appl. No.: 12/771,848

(22) Filed: Apr. 30, 2010

Related U.S. Application Data
(60) Provisional application No. 61/174,387, filed on Apr. 30, 2009.

(51) Int. Cl. H01L 31/105; H01L 21/22

(52) U.S. Cl. 257/458; 438/57; 257/E21.135; 257/E31.061

(57) ABSTRACT

Radiation-absorbing semiconductor devices and associated methods of making and using are provided. In one aspect, for example, a method for making a radiation-absorbing semiconductor device having enhanced photoresponse can include forming an active region on a surface of a low oxygen content semiconductor, and annealing the low oxygen content semiconductor to a temperature of from about 300° C. to about 1100° C., wherein the forming of the active region and the annealing of the low oxygen content semiconductor are performed in a substantially oxygen-depleted environment.

### PRIORITY DATA

This application claims the benefit of U.S. Provisional Patent Application Ser. No. 61/174,387, filed on Apr. 30, 2009, which is incorporated herein by reference.

### FIELD OF THE INVENTION

The present invention relates to radiation-sensitive semiconductor devices having low oxygen content semiconductor materials and methods for making the same. Accordingly, the present invention involves the electrical and material science fields.

### BACKGROUND

Various semiconductor devices can be used to absorb and detect photons. Such photo-detecting semiconductor devices are often affected by and provide some response to interaction with electromagnetic radiation. Various ranges of electromagnetic radiation can be detected by various photo-detecting semiconductor devices, including visible range wavelengths (approximately 400 nm to 700 nm) and non-visible wavelengths (longer than about 700 nm or shorter than 400 nm). The infrared spectrum is often thought of as including a near infrared portion of spectrum including wavelengths of approximately 700 to 1300 nm, a short wave infrared portion of the spectrum including wavelengths of approximately 1300 nm to 3 micrometers, and a mid to long wave infrared (or thermal infrared) portion of the spectrum including wavelengths greater than about 3 micrometers up to about 30 micrometers. These are generally and collectively referred to herein as “infrared” portions of the electromagnetic spectrum unless otherwise noted.

Current semiconductor devices are often formed from common silicon wafers. A typical silicon wafer can be produced by various manufacturing methods such as the Czochralski (CZ) method, the Float Zone (FZ) method, and the like. The CZ method involves introducing a single seed crystal into a molten silicon bath contained within a quartz crucible. Once heated to the desired temperature, the silicon molten mass is pulled from the molten bath and cooled, thus forming a silicon crystal. The silicon crystal is often cylindrical in shape, the diameter of which is determined in part by the temperature and rate at which the seed is pulled from the molten bath. Wafers commonly having diameters of, for example, 4 inches, 8 inches, and 12 inches can be formed from such cylindrical silicon crystals.

During the silicon crystal growth process, various dopants can be added (i.e. arsenic, boron, phosphorous, etc.) to give the silicon material desired characteristics (i.e. electrical properties). Often, however, non-desirable dopants or contaminants can also be introduced in this step. Such contaminants can create defects or defect sites in the silicon that can act as recombination centers for electron or hole electrical charge carriers that can in turn reduce the efficiency of the semiconductor device. Other growth methods have been developed to reduce the amounts of contaminants introduced in the crystal during the growth process, such as, for example, the FZ process.

FZ processes typically involve creating a mobile molten region in a portion of a polysilicon ingot using, for example, an inductor or RF coil. As the molten region moves through the ingot, it crystallizes as it cools. Impurities are mobilized and concentrated away from the crystallizing regions, thus allowing crystallization of a silicon ingot having fewer contaminants. This is due to the fact that impurities are more soluble in a molten state than a crystalline state and can thus be removed as the molten zone passes through the ingot.

### SUMMARY

The present disclosure provides radiation-absorbing semiconductor devices and associated methods of making and using such devices. In one aspect, for example, a method for making a radiation-absorbing semiconductor device having enhanced photoresponse can include forming an active region on a surface of a low oxygen content semiconductor, and annealing the low oxygen content semiconductor to a temperature of from about 300 C.° to about 1100 C.°, wherein formation of the active region and the annealing are performed in a substantially oxygen-depleted environment. In another aspect, the low oxygen content semiconductor is annealed to a temperature of from about 500 C.° to about 900 C.°. In one aspect, the enhanced photoresponse is a photoconductive gain response. In another aspect, the enhanced photoresponse is an external quantum efficiency response. In yet another aspect, the enhanced photoresponse can be both a photoconductive gain response and an external quantum efficiency response. Additionally, in one aspect the low oxygen content semiconductor is silicon.

Various annealing techniques can be utilized to anneal the low oxygen semiconductor, and any such technique is considered to be within the present scope. Non-limiting examples include rapid annealing processes, baking processes, and the like. In one aspect, the low oxygen content semiconductor is annealed by a rapid annealing process for a duration of greater than or equal to about 1 μs. In another aspect, the low oxygen content semiconductor is annealed by a baking anneal process for a duration of greater than or equal to about 1 ms.

The active region can be formed on or near a surface of the low oxygen content semiconductor via several techniques. It should be noted that the technique of forming such a region should not be seen as limiting, and all such techniques should be considered to be within the present scope. In one aspect, for example, forming the active region includes irradiating the surface of the low oxygen content semiconductor with laser radiation. In another aspect, irradiating the surface of the low oxygen content semiconductor includes exposing the surface to a dopant such that irradiation incorporates the dopant into the semiconductor. Various dopant materials are contemplated, depending on the desired properties of the active region and the techniques utilized to form such a region. Non-limiting examples of dopant materials can include S, F, B, P, N, As, Se, Te, Ge, Ar, Ga, In, Sb, and combinations thereof. It should be noted that the scope of dopant materials should include, not only the dopant materials themselves, but also materials in forms that deliver such dopants. For example, S dopant materials includes not only S, but also any material capable being used to dope S into the active region, such as, for example, H₂S, SF₆, SO₂, and the like.

Furthermore, in one aspect the responsivity of the radiation-absorbing semiconductor device is greater than or equal to about 0.1 A/W for at least a single radiation wavelength from about 1100 nm to about 3500 nm. In another aspect, the responsivity of the radiation-absorbing semiconductor device is greater than or equal to about 0.8 A/W for at least a single radiation wavelength from about 250 nm to about 1100 nm. In one aspect, these responsivity ranges are for low oxygen content silicon semiconductors.

In another aspect of the present disclosure, a radiation-absorbing semiconductor device having enhanced photoresponse is provided. Such a device can include a low oxygen content semiconductor having an active region formed thereon, wherein the low oxygen content semiconductor has been annealed to a temperature of from about 300 C.° to about 1100 C.° and the radiation-absorbing semiconductor has a responsivity of greater than or equal to about 0.1 A/W for at least a single radiation wavelength from about 1100 nm to about 3500 nm. In another aspect, the radiation-absorbing semiconductor has a responsivity that is greater than or equal to about 0.8 A/W for at least a single radiation wavelength from about 250 nm to about 1100 nm. Furthermore, in one aspect, the low oxygen content semiconductor has an oxygen content that is less than about 50 ppm atomic. In another aspect, the low oxygen content semiconductor has an oxygen content that is less than about 4 ppm atomic.

One factor that can enhance photoresponse is the average lifetime of charge carriers in the semiconductor material. In one aspect, the average charge carrier lifetime in the low oxygen content semiconductor is greater than or equal to about 500 μs. In another aspect, the average charge carrier lifetime in the low oxygen content semiconductor is greater than or equal to about 50 μs.

Another factor that can enhance photoresponse is the resistivity of the semiconductor. In one aspect, the resistivity of the low oxygen content semiconductor is greater than or equal to about 500 Ω-cm. In another aspect, the resistivity of the low oxygen content semiconductor is greater than or equal to about 1500 Ω-cm.

Furthermore, the radiation-absorbing devices of the present disclosure exhibit low dark current densities. In one aspect, for example, the dark current density in the radiation-absorbing device is less than or equal to about 10 μA/cm² operated at a bias voltage greater than 5V. In another aspect, the dark current density in the radiation-absorbing device is less than or equal to about 1 μA/cm² operated at a bias voltage greater than 5V. In yet another aspect, the dark current density in the radiation-absorbing device is less than or equal to about 0.5 μA/cm² operated at a bias voltage greater than 5V.

The radiation-absorbing semiconductors are operable to detect various electromagnetic radiation wavelengths. In one aspect, for example, the radiation-absorbing semiconductor is operable to detect electromagnetic radiation having a wavelength of from about 400 nm to about 3 μm. In another aspect, the radiation-absorbing semiconductor is operable to detect electromagnetic radiation having a wavelength of greater than about 1100 nm.

In yet another aspect of the present disclosure, a semiconductor device having enhanced photoconductive gain is provided. Such a device can include a radiation-absorbing semiconductor as has been described and having an n-type, an i-type, and a p-type region, wherein the i-type region has an oxygen content of less than 10 ppm atomic, and wherein the radiation-absorbing semiconductor has a responsivity greater than or equal to about 0.1 A/W for at least a single radiation wavelength from about 1100 nm to about 3500 nm.

### BRIEF DESCRIPTION OF THE DRAWINGS

FIG. 1 is a depiction of a method of making a radiation-absorbing semiconductor device having enhanced photoresponse in accordance with one embodiment of the present disclosure.

FIG. 2 is a graphical depiction of a radiation-absorbing semiconductor device in accordance with one embodiment of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

It should be noted that, as used in this specification and the appended claims, the singular forms “a,” and, “the” include plural referents unless the context clearly dictates otherwise. Thus, for example, reference to “a dopant” includes one or more of such dopants, and reference to “the wavelength” includes reference to one or more of such wavelengths.

### DEFINITIONS

In describing and claiming the present invention, the following terminology will be used in accordance with the definitions set forth below.

As used herein, the term “low oxygen content” refers to any material having an interstitial oxygen content that is less than or equal to about 60 ppm atomic.

As used herein, the term “target region” refers to an area of a semiconductor material that is intended to be doped or surface modified using laser radiation. The target region of a semiconductor material can vary as the surface modifying process progresses. For example, after a first target region is doped or surface modified, a second target region may be selected on the same semiconductor material.

As used herein, the terms “disordered surface” and “textured surface” can be used interchangeably, and refer to a surface having an undulating topology with nano- to micron-sized surface height variations formed by the irradiation of laser pulses. While the characteristics of such a surface can be highly variable depending on the materials and techniques employed, in one aspect such a surface can be several hundred nanometers thick and made up of nanocyrstallites (e.g. from about 10 to about 50 nanometers) and nanopores. In another aspect, such a surface can include micron-sized crystal structures (e.g. about 2 microns to about 60 microns).

As used herein, the term “fluence” refers to the amount of energy from a single pulse of laser radiation that passes through a unit area. In other words, “fluence” can be described as the energy density of one laser pulse.

As used herein, the terms “surface modifying” and “surface modification” refer to the altering of a surface of a semiconductor material using laser radiation. Surface modification can include processes using primarily laser radiation or laser radiation in combination with a dopant, whereby the laser radiation facilitates the incorporation of the dopant into a surface of the semiconductor material. Accordingly, in one aspect surface modification includes doping of a semiconductor material.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

### THE INVENTION

The present disclosure provides radiation-absorbing semiconductor devices having an enhanced photoresponse and associated methods of making and using such devices. It has now been discovered that various manufacturing techniques, including using low oxygen content semiconductor materials, can increase or otherwise enhance the photoresponse of radiation-absorbing semiconductor devices. Photoresponse can be enhanced through a variety of mechanisms. In one aspect, for example, enhanced photoresponse can be achieved through increasing the photoconductive gain response of the semiconductor material. In another aspect, enhanced photoresponse can be achieved through increasing the external quantum efficiency response of the semiconductor material. It should also be noted that these effects are not necessarily mutually exclusive, and in some aspects photoresponse can be enhanced through a combination of photoconductive gain and external quantum efficiency.

Photoconductive gain can be increased by, in one aspect for example, charge carriers traveling multiple loops within the device circuitry, thus generating gain. Thus, the ability of carriers to travel multiple loops without recombination can thus be a factor in increasing photoconductive gain. In order to make many loops in the circuitry, the carrier lifetime should be substantially longer than the time that such carriers travel a loop within the circuitry. Thus, photoconductive gain can be proportional to t/T, where t is the lifetime of the carrier and T is the travel time for the carrier to make one loop. As such, a long carrier lifetime is useful for increasing photoconductive gain.

In another aspect, photoconductive gain can be increased by minimizing the travel time of the carriers within the semiconductor device. Charge carriers travel in either a diffusion mode or a drift mode. Carriers traveling in diffusion mode are traveling thermally, while carriers traveling in drift mode are traveling within an electric field. Charge carriers travel in drift mode much faster than in diffusion mode because of the effects of the electric field. The carrier drift velocity can be characterized as in Equation 1:

v=μE Equation 1

where μ is the mobility of the carrier and E is the electric field strength. E is defined as in Equation 2:

E=V/d Equation 2

where d is the length of the electric field region in a photoconductor and V is the voltage drop (or bias) across the photoconductor. A larger voltage drop can, therefore, be beneficial to yield a stronger electric field, thus resulting in a faster carrier drift velocity. Various techniques could be utilized to increase the voltage drop across the device. In one aspect, for example, the voltage drop can be increased by increasing the resistance of the semiconductor. According to Ohm's Law, current through a conductor between two points is directly proportional to the potential difference or voltage across the two points, and inversely proportional to the resistance between them. Ohm's Law is shown for reference in Equation 3:

V=IR Equation 3

where V is the voltage, I is the current, and R is the resistance. Thus increasing the resistance of semiconductor materials from which a device is made can increase the voltage drop across the device, thereby increasing carrier velocity and decreasing carrier travel time. As has been described, such a decrease in travel time can increase photoconductive gain. It should be noted that increasing the resistance of a semiconductor material can also include maintaining the resistance of the material during processing, or in some cases, minimizing a decrease in resistance during processing.

As has been shown, photoconductive gain can be increased or enhanced by increasing the lifetime of the carriers and by decreasing or minimizing travel time of the carriers. These effects may not be mutually exclusive, however. For example, increasing carrier lifetime increases the number of loops that are made in the device circuitry. Decreasing travel time effectively increases the number of loops that can be made through the circuitry for a given carrier lifetime. Accordingly, some interdependency exists between these effects.

As indicated above, photoresponse can be increased or enhanced through external quantum efficiency. Described in terms of a solar cell, external quantum efficiency can be described as the current obtained outside the device per incoming photon. The external quantum efficiency therefore depends on both the absorption of light and the collection of charges. Once a photon has been absorbed and has generated an electron-hole pair, these charges are separated and collected at the junction. A material having a beneficial external quantum efficiency therefore exhibits low charge recombination. The “external” quantum efficiency of a device such as a silicon solar cell includes the effect of optical losses such as transmission and reflection. However, it is often useful to look at the quantum efficiency of the light remaining after the reflected and transmitted light has been lost. “Internal” quantum efficiency refers to the efficiency with which photons that are not reflected or transmitted out of the device can generate collectable carriers. By measuring the reflection and transmission of a device, the external quantum efficiency curve can be corrected to obtain the internal quantum efficiency curve. In general, external quantum efficiency (EQE) can be described as in Equation 4:

$$\begin{matrix}EQE = \frac{electrons \text{/} sec}{photons \text{/} sec} \\ = \frac{\begin{matrix}current \text{/} \\ ( charge of one electron )\end{matrix}}{\begin{matrix}( total power of photons ) \text{/} \\ ( energy of one photon )\end{matrix}}\end{matrix} \qquad Equation 4$$

It has been discovered that carrier lifetime and carrier travel time can be related to the amount of oxygen incorporated into the semiconductor lattice. Carrier lifetime tends to increase and carrier travel time tends to decrease in semiconductor materials having low oxygen content. As such, a low oxygen content semiconductor can be used as an effective starting material for making radiation-absorbing semiconductor devices having an enhanced photoresponse.

Oxygen can exist in different states or at different sites (for example, interstitially or substitutionally) within the silicon, dependent upon the thermal processing the silicon substrate has received. If the wafer is subjected to temperatures higher than, for example, about 1000° C., oxygen can form aggregates or clusters that serve as defect sites in the silicon lattice. These sites may result in trap states and a reduction in carrier lifetime within the semiconductor substrate and device. At lower temperatures (for example, around 400° C. to 700° C.), oxygen can behave as electrically active thermal donors. Thus, oxygen can have a negative impact on carrier lifetime and on carrier mobility. In a device fabricated to have photoconductive gain, the presence of oxygen causing reduced carrier lifetime may result in reduced levels of photoconductive gain.

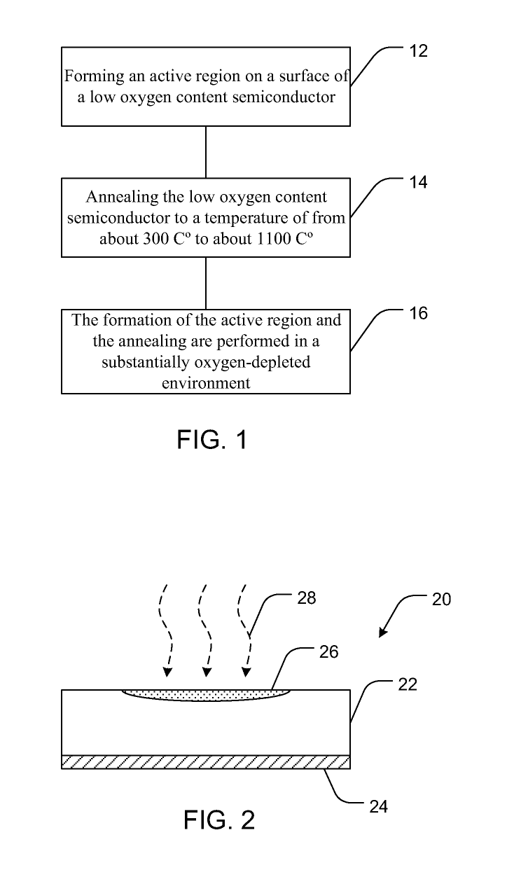

It may be beneficial, therefore, to produce various semiconductor devices such that a low oxygen content is obtained or maintained. This can be accomplished in a variety of ways, including using semiconductor materials having low levels of oxygen contained therein, processing the semiconductor materials in a manner that minimizes the uptake of oxygen into the semiconductor lattice, utilizing techniques to eliminate or reduce oxygen that may be present in the semiconductor, and the like. Accordingly, in one aspect of the present disclosure shown in FIG. 1, a method for making a radiation-absorbing semiconductor device having enhanced photoresponse can include forming an active region on a surface of a low oxygen content semiconductor 12 and annealing the low oxygen content semiconductor to a temperature of from about 300 C.° to about 1100 C.° 14, wherein the forming of the active region and the annealing of the low oxygen content semiconductor are performed in a substantially oxygen-depleted environment 16. Thus it may be beneficial to utilize a semiconductor material having a low oxygen content and to process the semiconductor material in an oxygen-depleted environment in order to maintain the low-oxygen content of the material. Processing the semiconductor material in an oxygen-depleted environment can include a variety of environments. In one aspect, for example, the oxygen-depleted environment can be an environment whereby oxygen from the air or other sources has been replaced with a gas or other fluid containing little to no oxygen. In another aspect, processing can occur in a vacuum environment, and thus contain little to no oxygen. Additionally, oxygen-containing materials or materials that introduce oxygen into the semiconductor, such as, for example, quartz crucibles, can be avoided. As a practical matter, the term “oxygen-depleted environment” can be used to describe an environment with low levels of oxygen, provided a low oxygen content semiconductor can be processed therein within the desired tolerances. Thus, environments having low oxygen, or little to no oxygen, are environments in which a semiconductor can be processed as a low-oxygen content semiconductor while maintaining oxygen levels within the tolerances of the present disclosure. In one aspect, an oxygen-depleted environment can be an oxygen-free environment.

A passivation layer can further be disposed over at least portion of the low oxygen content semiconductor material and more particularly over a portion of the active region. Such a passivation layer can be comprised of an inert material such as, for example, silicon dioxide SiO₂. The passivation layer can serve to confine the electrical mobility within the device and also maintain the oxygen content at the desired levels.

Depending on the desired semiconductor device and the level of photoresponse, a variety of semiconductor materials and oxygen contents are contemplated. Such semiconductor materials can be made by various current manufacturing procedures, such as Czochralski (Cz) processes, magnetic Czochralski (mCz) processes, Float Zone (FZ) processes, epitaxial growth processes, and the like. Various processes produce semiconductor materials containing varying amounts of oxygen, and as such, some applications having more stringent tolerances with respect to oxygen levels may benefit more from certain manufacturing procedures as compared to others. For example, during CZ crystal growth, oxygen from the containment vessel, usually a quartz crucible, can become incorporated into the crystal as it is pulled. Additionally, other sources of oxygen contamination are also possible with the CZ process. Such contamination may be reduced, however, through the use of non oxygen-containing crucible materials, as well as the development of other crystal growth methods that do not utilize a crucible. One such process is the FZ process that has been described herein.

Substrates grown with the CZ method can also be made to have lowered oxygen concentration through enhancements to the crystal growth process, such as growing the crystal in the presence of a magnetic field (i.e. the mCz process). Also, gettering techniques can be employed to reduce the impact of oxygen or other impurities on the finished device. These gettering techniques can include thermal cycles to liberate or nucleate impurities, or selective ion implantation of species to serve as gettering sites for the impurities. For example, oxygen concentrated in the semiconductor can be removed by the performing a furnace cycle to form a denuded zone. During heating with an inert gas, oxygen near the surface of the semiconductor diffuses out of the material. During the furnace cycle but after the denuding step, nucleating and growing steps may be performed. Nucleating sites for precipitates are formed during the nucleating step, and the precipitates are grown from the nucleating sites during a growing step. The precipitates are formed from interstitial oxygen within the bulk of the semiconductor material and beneath the denuded zone. The precipitation of oxygen in the bulk of semiconductor material can be desired because such precipitates can act as gettering sites. Such precipitate formation can also be performed to “lock up” interstitial oxygen into the precipitates and reduce the likelihood that such oxygen can migrates from the bulk of the semiconductor material into the denuded zone

In another aspect, an additional step of growing a low oxygen content epitaxial layer of a semiconductor is provided. Epitaxial growth can be carried out via a number of processes known to those skilled in the art. Epitaxial deposition is essentially the process of utilizing a semiconductor wafer as a seed crystal, followed by the deposition of a film from a gaseous or liquid precursor on the wafer. Depending on the process, the film can take on the lattice structure and orientation identical to the wafer. This step can ensure that the top surface of the wafer has the desired oxygen content prior to forming the active region with a laser step. In addition, it should be noted that during the epitaxial deposition step other dopants may be incorporated into the semiconductor material. Depositing other thin films on the semiconductor material to achieve the desired oxygen concentration is also contemplated herein.

It is also contemplated that additional techniques can be used to maintain the low oxygen concentration in the semiconductor material. For example, utilizing a silicon (or semiconductor) on insulator (SOI) wafer, minimizing exposure to moisture and oxidizing environments, removing adsorbed moisture, removing native oxide, removing grinding and polish damage, designing optimal backside finish, removing oxygen and moisture from the lasing environment, introducing dopant species to wafer surface, controlling carbon and fluorine introduction into the substrate, providing sufficient clean reactive species, optimizing species incorporation for activation and to minimize recombination centers, controlling sheet carrier density and dopant species (e.g. n-type or p-type), controlling wafer bow and thickness variation within operating range of depth of focus, and/or controlling strain within the semiconductor material. The methods and steps disclosed herein can be beneficial in increasing charge carrier lifetime, increasing resistivity of the semiconductor, and thus ultimately creating a device having increased delectability of electromagnetic radiation and photoconductive gain.

Regardless of the manufacturing process used, in one aspect a low oxygen content semiconductor can have an oxygen content that is less than or equal to about 50 ppm atomic. In another aspect, a low oxygen content semiconductor can have an oxygen content that is less than or equal to about 30 ppm atomic. In yet another aspect, a low oxygen content semiconductor can have an oxygen content that is less than or equal to about 10 ppm atomic. In a further aspect, the low oxygen content semiconductor can have an oxygen content that is less than or equal to about 4 ppm atomic. In yet a further aspect, the low oxygen content semiconductor can have an oxygen content that is less than or equal to about 1 ppm atomic.

A variety of techniques of forming an active region on the low oxygen content semiconductor material are contemplated, and any technique capable of forming such a region should be considered to be within the present scope. In one aspect, for example, a target region of the semiconductor material can be irradiated with laser radiation to form an active region such as a substantially disordered surface. In another aspect, irradiating the surface of the low oxygen content semiconductor includes exposing the laser radiation to a dopant such that irradiation incorporates the dopant into the semiconductor. Various dopant materials are known in the art, and are discussed in more detail herein.

Additionally, lasers and laser radiation are well known in the art. The type of laser radiation used to surface modify a semiconductor material can vary depending on the material and the intended modification. Any laser radiation known in the art can be used with the systems and methods of the present disclosure. There are a number of laser characteristics that can affect the surface modification process and/or the resulting product including, but not limited to the wavelength of the laser radiation, pulse width, pulse fluence, pulse frequency, polarization, laser propagation direction relative to the semiconductor material, etc. In one aspect, a laser can be configured to provide pulsatile lasing of a semiconductor material. Such laser pulses can have a central wavelength in a range of about from about 10 nm to about 8 μm, and more specifically from about 200 nm to about 1200 nm. The pulse width of the laser radiation can be in a range of from about tens of femtoseconds to about hundreds of nanoseconds. In one aspect, laser pulse widths can be in the range of from about 50 femtoseconds to about 50 picoseconds. In another aspect, laser pulse widths are in the range of from about 50 to 500 femtoseconds.

The number of laser pulses irradiating a semiconductor target region can be in a range of from about 1 to about 2000. In one aspect, the number of laser pulses irradiating a semiconductor target region can be from about 2 to about 1000. Further, the repetition rate or frequency of the pulses can be selected to be in a range of from about 10 Hz to about 10 μHz, or in a range of from about 1 kHz to about 1 MHz, or in a range from about 10 Hz to about 1 kHz. Moreover, the fluence of each laser pulse can be in a range of from about 1 kJ/m² to about 20 kJ/m², or in a range of from about 3 kJ/m² to about 8 kJ/m².

As has been described, annealing the low oxygen content semiconductor can enhance the photoresponse properties of the material. It has also been discovered that annealing the semiconductor at “lower” temperatures can greatly enhance the photoconductive gain and external quantum efficiency of radiation-absorbing devices utilizing such materials. In one aspect, for example, the low oxygen content semiconductor can be annealed to a temperature of from about 300° C. to about 1100 C.°. In another aspect, the low oxygen content semiconductor can be annealed to a temperature of from about 500° C. to about 900° C. In yet another aspect, the low oxygen content semiconductor can be annealed to a temperature of from about 700° C. to about 800° C. In a further aspect, the low oxygen content semiconductor can be annealed to a temperature that is less than or equal to about 850° C.

The duration of the annealing procedure can vary according to the specific type of anneal being performed, as well as according to the various materials being used and additional desired results. For example, rapid annealing processes can be used, and as such, durations of the anneal may be shorter as compared to other techniques. Various rapid thermal anneal techniques are known, all of which should be considered to be within the present scope. In one aspect, the low oxygen content semiconductor can be annealed by a rapid annealing process for a duration of greater than or equal to about 1 μs. In another aspect, the duration of the rapid annealing process can be from about 1 μs to about 1 ms. As another example, a baking or furnace anneal process can be used having durations that may be longer compared to a rapid anneal. In one aspect, for example, the low oxygen content semiconductor can be annealed by a baking anneal process for a duration of greater than or equal to about 1 ms to several hours.

Turning now to FIG. 2, a cross-sectional illustration of a radiation-absorbing semiconductor device 20 having an enhanced photoresponse according to one aspect of the present disclosure is shown. Such a device can include a low oxygen content semiconductor material 22, and in some aspects, a substrate or other handler 24 material can be coupled to the semiconductor. An active region 26 can be formed on a surface of the low oxygen content semiconductor material 22. The active region 26 can be a substantially disordered or textured surface configured to absorb incident electromagnetic radiation 28. The depth of the active region can be in the range of from about 1 nm to about 2000 nm. In an alternative embodiment, the active region may be formed near the backside of the semiconductor material, such that electromagnetic radiation incident on the semiconductor material passes therethrough prior to detection and absorption by the active region (not shown).

A variety of low oxygen content semiconductor materials are contemplated for use with the methods and devices according to aspects of the present disclosure. Non-limiting examples of such semiconductor materials can include group IV materials, group II-VI materials, and group III-V materials from the periodic table. More specifically, exemplary group IV materials can include silicon, carbon (e.g. diamond), germanium, and combinations thereof. Various combinations of group IV materials can include silicon carbide (SiC) and silicon germanium (SiGe). In one specific aspect, the low oxygen content semiconductor can be or include silicon. It should be noted that amorphous moieties are also included in the group IV materials and those that follow. Exemplary amorphous materials include amorphous diamond and amorphous silicon.

Exemplary group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlₓGa₁₋ₓAs), indium gallium arsenide (InGaAs, InₓGa₁₋ₓAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

In one aspect, the low oxygen content semiconductor material can be at least one of silicon, carbon, germanium, aluminum nitride, gallium nitride, indium gallium arsenide, aluminum gallium arsenide, and combinations thereof. In one specific aspect, the semiconductor material can be silicon having an oxygen content less than about 10 ppm atomic. In another aspect the silicon can have an oxygen content less than about 5 ppm atomic. In yet another aspect the silicon can have an oxygen content less than about 1 ppm atomic.

Furthermore, the low oxygen content semiconductor material can include multiple layers that vary in majority carrier polarity (i.e. donor or acceptor impurities). The donor or acceptor impurities are often determined by the type of dopant/impurities introduced into the semiconductor either through a growth process, deposition process, epitaxial process, implant process, lasing process, or other known process to those skilled in the art. One skilled in the art understands that semiconductor materials can include an n-type layer, an intrinsic (i-type) layer, and a p-type layer. These layers together can collectively be referred to as a p-i-n semiconductor material stack that creates a junction. A semiconductor material devoid of an i-type layer is also contemplated. In other aspects the semiconductor material may include multiple junctions or a heterojunction. Accordingly, in one aspect a low oxygen content semiconductor can include at least one of a p-type region, an n-type region, an i-type region, and combinations thereof.

n-type and p-type materials can be made by doping, as is well known in the art. In the case of n-type materials, doping creates an increase in the number of free negative charge carriers. In the case of p-type materials, doping creates an increase in the number of free positive charge carriers. In some aspects, variations of n(−−), n(−), n(+), n(++), p(−−), p(−), p(+), or p(++) type semiconductor layers may be used, whereby minus and positive signs are indicators of the relative strength of the doping of the semiconductor material. An intrinsic (i-type) semiconductor is typically a substantially undoped semiconductor. It is also contemplated that the different layers or regions may vary in oxygen content.

Various techniques of forming an active region on a low oxygen content semiconductor layer are contemplated, and any such surface modification method should be considered to be within the present scope. In one aspect, for example, the active region can be formed by passing a laser across a surface of the semiconductor material in the area or region where the active region is to be formed. Examples of such processing have been described in further detail in U.S. Pat. Nos. 7,057,256, 7,354,792 and 7,442,629, which are incorporated herein by reference in their entireties. Briefly, a surface of a semiconductor material is irradiated with laser radiation to form a textured or surface modified region (i.e. the active region). Such laser processing can occur with or without a dopant material. In those aspects whereby a dopant is used, the laser can be directed through a dopant carrier and onto the semiconductor surface. In this way, dopant from the dopant carrier is introduced into the active region of the semiconductor material. An active region incorporated in a semiconductor material can have several benefits in accordance with aspects of the present disclosure. For example, the active region typically has a textured surface that increases the surface area of the active region and increases the probability of a photon being absorbed.

A variety of dopant materials are contemplated, and any such material that can be used to surface modify a semiconductor material according to aspects of the present disclosure should be considered to be within the present scope. It should be noted that the particular dopant utilized can vary depending on the semiconductor being surface modified, and the intended use of the resulting semiconductor material. A dopants can be either electron donating or hole donating. In one aspect, non-limiting examples of dopant materials can include S, F, B, P, N, As, Se, Te, Ge, Ar, Ga, In, Sb, and combinations thereof. It should be noted that the scope of dopant materials should include, not only the dopant materials themselves, but also materials in forms that deliver such dopants (i.e. dopant carriers). For example, S dopant materials includes not only S, but also any material capable being used to dope S into the active region, such as, for example, H₂S, SF₆, SO₂, and the like, including combinations thereof. Non-limiting examples of fluorine-containing compounds can include ClF₃, PF₅, F₂ SF₆, BF₃, GeF₄, WF₆, SiF₄, HF, CF₄, CHF₃, CH₂F₂, CH₃F, C₂F₆, C₂HF₅, C₃F₈, C₄F₈, NF₃, and the like, including combinations thereof. Non-limiting examples of boron-containing compounds can include B(CH₃)₃, BF₃, BCl₃, BN, C₂B₁₀H₁₂, borosilica, B₂H₆, and the like, including combinations thereof. Non-limiting examples of phosphorous-containing compounds can include PF₅, PH₃, and the like, including combinations thereof. Non-limiting examples of chlorine-containing compounds can include Cl₂, SiH₂Cl₂, HCl, SiCl₄, and the like, including combinations thereof. Dopants can also include arsenic-containing compounds such as AsH₃ and the like, as well as antimony-containing compounds. Additionally, dopant materials can include mixtures or combinations across dopant groups, i.e. a sulfur-containing compound mixed with a chlorine-containing compound. In one aspect, the dopant material can have a density that is greater than air. In one specific aspect, the dopant material can include Se, H₂₅, SF₆, or mixtures thereof. In yet another specific aspect, the dopant can be SF₆ and can have a predetermined concentration range of 5.0×10⁻⁸ mol/cm³-5.0×10⁻⁴ mol/cm³. SF₆ gas is a good carrier for the incorporation of sulfur into the semiconductor material via a laser process without significant adverse effects on the semiconductor material. Additionally, it is noted that dopants can also be liquid solutions of n-type or p-type dopant materials dissolved in a solution such as water, alcohol, or an acid or basic solution. Dopants can also be solid materials applied as a powder or as a suspension dried onto the wafer.

Radiation absorbing devices according to aspects of the present disclosure can be configured to detect electromagnetic radiation having a variety of wavelength ranges. In one aspect, for example, the radiation-absorbing semiconductor is operable to detect electromagnetic radiation having a wavelength of from about 400 nm to about 3 μm. In another aspect, the radiation-absorbing semiconductor is operable to detect electromagnetic radiation having a wavelength of greater than about 1100 nm. Additionally, in another aspect, responsivity of the radiation-absorbing semiconductor device is greater than or equal to about 0.1 A/W for at least a single radiation wavelength from about 1100 nm to about 3500 nm. In yet another aspect, responsivity of the radiation-absorbing semiconductor device is greater than or equal to about 0.8 A/W for at least a single radiation wavelength from about 250 nm to about 1100 nm. Additionally, such a device may be operated at a bias less than about 20V.

As has been described, charge carrier lifetime can affect the photoconductive gain of the semiconductor material. Longer carrier lifetimes generally relate to greater photoconductive gains. The semiconductor materials according to aspects of the present disclosure have enhanced carrier lifetimes as compared to prior art semiconductor materials. In one aspect, for example, the average charge carrier lifetime in the low oxygen content semiconductor is greater than or equal to about 50 μs. In another aspect, the average charge carrier lifetime in the low oxygen content semiconductor is greater than or equal to about 500 μs.

Resistivity of the low oxygen content semiconductor, as has been described, can also affect the photoconductive gain and external quantum efficiency of such devices. By increasing the semiconductor resistance, the speed at which charge carriers move is increased. In one aspect, the resistivity of the low oxygen content semiconductor is greater than or equal to about 500 Ω-cm. In another aspect, the resistivity of the low oxygen content semiconductor is greater than or equal to about 1500 Ω-cm.

Another property that can influence photoconductive gain is dark current. Dark current can be defined as electric current that flows in a photosensitive device when no photons are entering the device. Significant levels of dark current in a device can greatly reduce photoconductive gain. The radiation-absorbing semiconductor devices according to aspects of the present disclosure exhibit low dark current as compared to the prior art. In one aspect, for example, dark current density in the radiation-absorbing device is less than or equal to about 10 μA/cm² operated at a bias voltage greater than 5V. In another aspect, the dark current density in the radiation-absorbing device is less than or equal to about 1 μA/cm² operated at a bias voltage greater than 5V. In yet another aspect, the dark current density in the radiation-absorbing device is less than or equal to about 0.5 μA/cm² operated at a bias voltage greater than 5V.

### Example

A silicon substrate having a resistivity of about 1000 ohm-cm and oxygen concentration of less than 10 pmm atomic is used in the following example. An n-type doped region is formed on the silicon substrate with phosphorus implantation. The silicon substrate is thermally annealed at 900° C. for 30 minutes. The resulting radiation-absorbing semiconductor devices have a dark current density of about 0.1 μA/cm² and responsivities of about 30 A/W at about 900 nm and about 0.3 A/W at about 1200 nm at 5V bias voltage.

Of course, it is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method for making a radiation-absorbing semiconductor device having enhanced photoresponse, comprising:
forming an active region on a surface of a low oxygen content semiconductor; and
annealing the low oxygen content semiconductor to a temperature of from about 300° C. to about 1100° C., wherein the forming of the active region and the annealing of the low oxygen content semiconductor are performed in a substantially oxygen-depleted environment.

2. The method of claim 1, wherein the low oxygen content semiconductor is annealed to a temperature of from about 500° C. to about 900° C.

3. The method of claim 1, wherein the low oxygen content semiconductor is annealed by a rapid annealing process for a duration of greater than or equal to about 1 μs

4. The method of claim 1, wherein the low oxygen content semiconductor is annealed by a baking anneal process for a duration of greater than or equal to about 1 ms.

5. The method of claim 1, wherein the enhanced photoresponse is a photoconductive gain response.

6. The method of claim 1, wherein the enhanced photoresponse is an external quantum efficiency response.

7. The method of claim 1, wherein forming the active region includes irradiating the surface of the low oxygen content semiconductor with laser radiation to form a substantially disordered surface.

8. The method of claim 7, wherein irradiating the surface of the low oxygen content semiconductor includes exposing the laser radiation to a dopant such that irradiation incorporates the dopant into the semiconductor.

9. The method of claim 8, wherein the dopant includes a member selected from the group consisting of S, F, B, P, N, As, Se, Te, Ge, Ar, Ga, In, Sb, and combinations thereof.

10. The method of claim 1, wherein responsivity of the radiation-absorbing semiconductor device is greater than or equal to about 0.1 A/W for at least a single radiation wavelength from about 1100 nm to about 3500 nm.

11. The method of claim 1, wherein responsivity of the radiation-absorbing semiconductor device is greater than or equal to about 0.8 A/W for at least a single radiation wavelength from about 250 nm to about 1100 nm.

12. The method of claim 1, wherein the low oxygen content semiconductor is silicon.

13. A radiation-absorbing semiconductor device having enhanced photoresponse, comprising:
a low oxygen content semiconductor having an active region formed thereon, wherein the low oxygen content semiconductor has been annealed to a temperature of from about 300° C. to about 1100° C. and the radiation-absorbing semiconductor has a responsivity of greater than or equal to about 0.1 A/W for at least a single radiation wavelength from about 1100 nm to about 3500 nm.

14. The radiation-absorbing semiconductor device of claim 13, wherein average charge carrier lifetime in the low oxygen content semiconductor is greater than or equal to about 50 μs.

15. The radiation-absorbing semiconductor device of claim 13, wherein average charge carrier lifetime in the low oxygen content semiconductor is greater than or equal to about 500 μs.

16. The radiation-absorbing semiconductor device of claim 13, wherein the resistivity of the low oxygen content semiconductor is greater than or equal to about 500 Ω-cm.

17. The radiation-absorbing semiconductor device of claim 13, wherein the resistivity of the low oxygen content semiconductor is greater than or equal to about 1500 Ω-cm.

18. The radiation-absorbing semiconductor device of claim 13, wherein the low oxygen content semiconductor has an oxygen content that is less than or equal to about 50 ppm atomic.

19. The radiation-absorbing semiconductor device of claim 13, wherein the low oxygen content semiconductor has an oxygen content that is less than or equal to about 4 ppm atomic.

20. The radiation-absorbing semiconductor device of claim 13, wherein dark current density in the radiation-absorbing device is less than or equal to about 10 μA/cm² operated at a bias voltage greater than 5V.

21. The radiation-absorbing semiconductor device of claim 13, wherein the dark current density in the radiation-absorbing device is less than or equal to about 1 μA/cm² operated at a bias voltage greater than 5V.

22. The radiation-absorbing semiconductor device of claim 13, wherein the dark current density in the radiation-absorbing device is less than or equal to about 0.5 μA/cm² operated at a bias voltage greater than 5V.

23. The radiation-absorbing semiconductor of claim 13, wherein the low oxygen content semiconductor includes a member selected from the group consisting of p-type regions, an n-type regions, and i-type regions, and combinations thereof.

24. The radiation-absorbing semiconductor of claim 13, wherein the radiation-absorbing semiconductor has a responsivity that is greater than or equal to about 0.8 A/W for at least a single radiation wavelength from about 250 nm to about 1100 nm.

25. The radiation-absorbing semiconductor of claim 13, wherein the radiation-absorbing semiconductor is operable to detect electromagnetic radiation having a wavelength of from about 400 nm to about 3 μm.

26. The radiation-absorbing semiconductor device of claim 13, wherein the radiation-absorbing semiconductor is operable to detect electromagnetic radiation having a wavelength of greater than about 1100 nm.

27. A semiconductor device having enhanced photoconductive gain, comprising:
a radiation-absorbing semiconductor as in claim 13 and having an n-type, an i-type, and a p-type region, and wherein the i-type region has an oxygen content of less than 10 ppm, and wherein the radiation-absorbing semiconductor has a responsivity greater than or equal to about 0.1 A/W for at least a single radiation wavelength from about 1100 nm to about 3500 nm.
